(19) United States
(12) Patent Application Publication
(10) Pub. No.: US 2008/0296751 A1
(43) Pub. Date: Dec. 4, 2008

(54) Semiconductor package

(75) Inventor: Wen-Jeng Fan, Hukou Shiang (TW)

Correspondence Address: Joe McKinney Muncy, PO Box 1364, Fairfax, VA, 22038-1364, US

(73) Assignee: POWERTECH TECHNOLOGY INC.

(21) Appl. No.: 11/806,031

(22) Filed: May 29, 2007

(51) Int. Cl. H01L 23/48

(52) U.S. Cl. 257/693; 257/E23.01

(57) ABSTRACT

A semiconductor package is revealed, primarily comprising a substrate, a chip disposed on the substrate, and an encapsulant to encapsulate the chip. The substrate has a plurality of dimples formed in its top surface thereof without penetrating through the substrate and located at a non-wiring region outside a chip mounting region. Therefore, without changing the appearance of the semiconductor package, the diffusion path of moisture and the adhesive strength between the encapsulant and the substrate can be increased to achieve functions of anti-humidity and anti-delamination.

### FIELD OF THE INVENTION

The present invention relates to a semiconductor package, especially, to a semiconductor package with enhanced functions of anti-moisture and anti-delamination.

### BACKGROUND OF THE INVENTION

In semiconductor packages, especially for Ball Grid Array (BGA), Land Grid Array (LGA), or memory card packages, chip(s) is disposed on a top surface of a wiring substrate and is encapsulated by Epoxy Molding Compound (EMC). The bottom surface of the substrate is exposed to dispose a plurality of solder balls or external terminals for electrical connections to other printed circuit boards. Normally, the EMC formed on the top surface of the substrate doesn't cover the edges of the substrate to avoid contaminations of the bottom surface by EMC bleeding. However, during moisture sensitivity test or temperature cycle test, the issues of delamination or popcorn are occurred between the substrate and the encapsulant to impact the reliability and the quality of the semiconductor packages.

As shown in FIG. 1, a conventional semiconductor package 100 primarily comprises a substrate 110, a chip 120, and an encapsulant 130. The substrate 110 has a top surface 111, a bottom surface 112, and a plurality of outer pads 113 disposed on the bottom surface 112. The chip 120 has a plurality of bonding pads 121 and is attached to the top surface 111 of the substrate 110 by a die-attaching layer 160 with the bonding pads 121 face upward where then the bonding pads 121 of the chip 120 are electrically connected to the substrate 110 by a plurality of bonding wires 140. The encapsulant 130 is formed on the top surface 111 to encapsulate the chip 120 and the bonding wires 140. A plurality of solder balls 150 are disposed on the outer pads 113 of the substrate 110 as external terminals of the semiconductor package 100. After a long-term operation or test of the semiconductor package 100, the delamination will occur at the bonding interface between the substrate 110 and the encapsulant 130. As shown in FIG. 1, moisture will absorb and diffuse along the top surface 111 of the substrate 110 and eventually reach the chip 120 and the die-attaching layer 160 leading to delamination. When the moisture diffusing to the die-attaching layer 160 will be absorbed and kept in the die-attaching layer 160. During long-term operations, the chip 120 will generate heat which moisture absorbed by the die-attaching layer 160 will be heated, evaporated, and exploded, eventually leading to popcorn.

In a known Ball Grid Array Package, through holes penetrate through the substrate and are disposed at the peripheries of the chip where the encapsulant fills the through holes and protrudes from the bottom surface of the substrate in order to increase the adhesive strength between the encapsulant and the substrate and to avoid diffusion of moisture. However, the EMC will easily form on the bottom surface of the substrate leading to contamination of outer pads since the encapsulant flows through the through holes. Moreover, the appearance of the final products has been changed and the substrate layout needs to be redesigned.

### SUMMARY OF THE INVENTION

The main purpose of the present invention is to provide a semiconductor package with the design of dimples in the substrate without changing the appearance of the products to increase the adhesive strength between the encapsulant and the substrate and to increase the diffusion path of moisture to achieve the functions of anti-humidity and anti-delamination.

The second purpose of the present invention is to provide a semiconductor package to avoid EMC bleeding on the ball placement surface of the substrate without changing the layout of the substrate.

According to the present invention, a semiconductor package primarily comprises a substrate, a chip, and an encapsulant. The substrate has a top surface and a plurality of dimples formed in the top surface. A chip mounting region is defined on the top surface where the dimples are disposed at a non-wiring region outside the chip mounting region without penetrating through the substrate. The chip is disposed in the chip mounting region. The encapsulant is formed on the top surface of the substrate to encapsulate the chip and the dimples.

### DESCRIPTION OF THE DRAWINGS

FIG. 1 shows a cross sectional view of a conventional semiconductor package.

FIG. 2 shows a cross sectional view of a semiconductor package according to the first embodiment of the present invention.

FIG. 3 shows a top view of the semiconductor package before encapsulation according to the first embodiment of the present invention.

FIG. 4 shows a cross sectional view of a semiconductor package according to the second embodiment of the present invention.

FIG. 5 shows a top view of the semiconductor package before encapsulation according to the second embodiment of the present invention.

FIG. 6 shows a cross sectional view of a semiconductor package according to the third embodiment of the present invention.

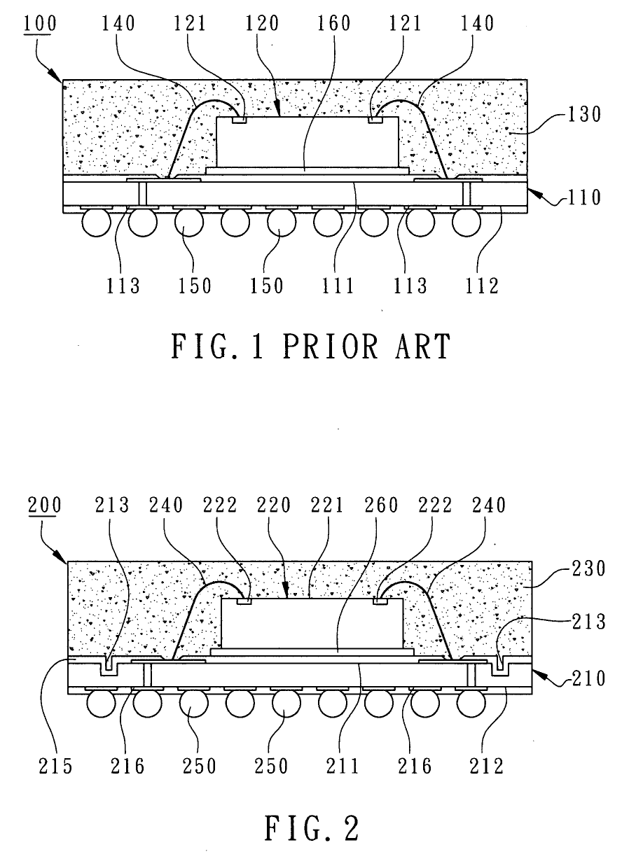

### DETAIL DESCRIPTION OF THE INVENTION

Please refer to the attached drawings, the present invention will be described by means of embodiment(s) below.

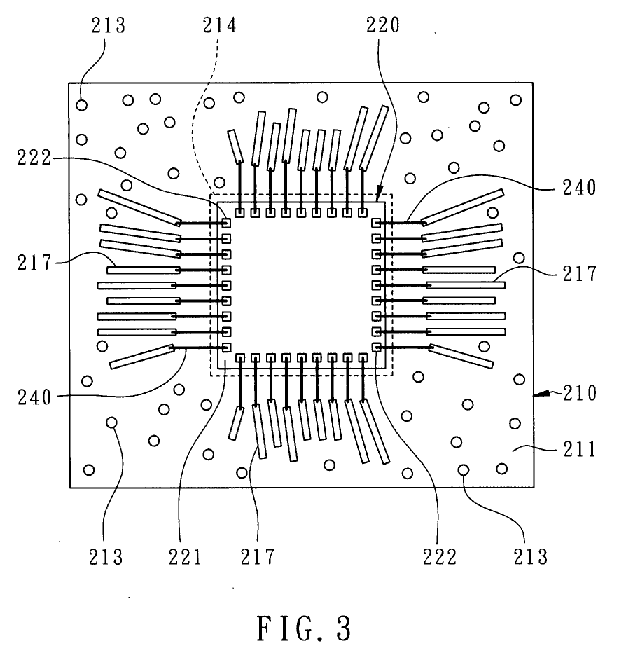

According to the first embodiment of the present invention, as shown in FIG. 2, a semiconductor package 200 primarily comprises a substrate 210, a chip 220, and an encapsulant 230. The substrate 210 has a top surface 211, a bottom surface 212, and a plurality of dimples 213 where the dimples 213 are formed in the top surface 211 but not penetrate through the substrate 210. As shown in FIG. 2 and FIG. 3, a chip mounting region 214 is defined on the top surface 211 to attach the chip 220. The dimples 213 are located at a non-wiring region outside the chip mounting region 214 without any electrical transmission. Therefore, when forming the dimples 213, the trace layer 217 and internal wiring pattern(s) in the substrate 210 will not be damaged, as shown in FIG. 3. In the present embodiment, the dimples 213 can be blind vias formed by mechanical drilling, preferably, the dimples are adjacent to the peripheries of the top surface 211 of the substrate 210, i.e., most of the distance from the dimples 213 to the peripheries of the top surface 211 of the substrate 210 is shorter than to the one from the dimples 213 to the chip mounting region 214. As shown in FIG. 2, the substrate 210 further has a solder mask 215 formed on the top surface 211 to cover the dimples 213. The depth of the dimples 213 ranges from one tenth to one half of the substrate thickness.

As shown in FIG. 3, in the present embodiment, the dimples 213 have circular openings and are distributed at the corners of the top surface 211 of the substrate 210 to partially reinforce the weaker portion between the substrate 210 and the encapsulant 230. The substrate 210 further has a plurality of outer pads 216 formed on the bottom surface 212.

The chip 220 is attached to the chip mounting region 214 on the top surface 211 of the substrate 210 by a die-attaching layer 260 where the chip 220 has an active surface 221 and a plurality of bonding pads 222 formed on the active surface 221. The chip 220 is electrically connected to the substrate 210 by a plurality of bonding wires 240 bonded from the bonding pads 222 to the substrate 210.

The encapsulant 230 is formed on the top surface 211 of the substrate 210 to encapsulate the chip 220 and the bonding wires 240. In the present embodiment, the encapsulant 230 is an Epoxy Molding Compound (EMC) formed on the top surface 211 of the substrate 210 by transfer molding. The semiconductor package 200 further has a plurality of solder balls 250 disposed on the outer pads 216 on the bottom surface 212 of the substrate 210 for electrical connections to external printed circuit boards.

Therefore, the substrate 210 with the design of dimples 213 can increase the diffusion path of moisture to extend the diffusion time of moisture to reach the chip mounting region 214 of the semiconductor package 200. Moreover, the dimples 213 can enhance the adhesive strength between the substrate 210 and the encapsulant 230 to avoid delamination to increase the reliability and the quality of the semiconductor package 200. Furthermore, since the dimples 213 without penetrating through the substrate 210, therefore, the appearance of the product and the trace layout of the substrate 210 will not be changed and the contamination of outer pads 216 on the bottom surface 212 of the substrate 210 due to EMC bleeding can be avoided. Moreover, the formation cost of the dimples 213 is relatively low without damaging the trace layer 217 of the substrate 210. More advantageously, the appearance of the semiconductor package 200 is as the same as that of the conventional semiconductor package 100.

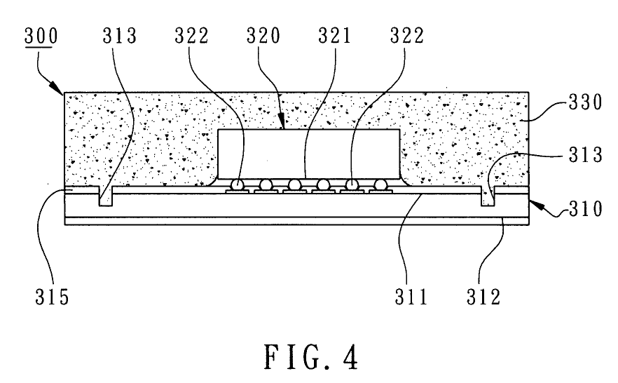

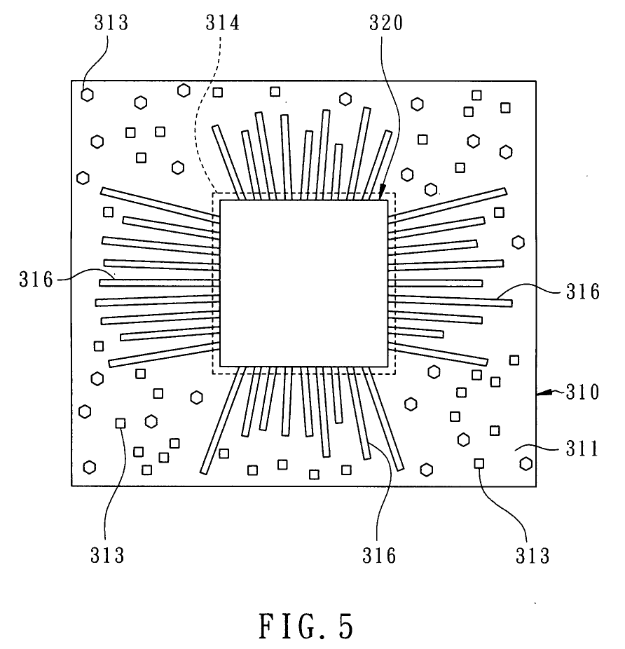

In the second embodiment, another semiconductor package 300 is revealed, as shown in FIG. 4, primarily comprising a substrate 310, a chip 320, and an encapsulant 330. The substrate 310 has a top surface 311, a bottom surface 312, and a plurality of dimples 313 formed in the top surface 311 of the substrate 310. A chip mounting region 314 is defined on the top surface 311. The dimples 313 are located at a non-wiring region outside the chip mounting region 314 without penetrating through the substrate 310 so that the trace layout 316 of the substrate 310 will not be damaged. In the present embodiment, the dimples 313 are selected from the group consisting of laser-drilled holes and punched indentations. A solder mask 315 is formed on the top surface 311 of the substrate 310 to expose the dimples 313. In the present embodiment, since the dimension of the openings of the solder mask 315 is the same as the one of the dimples 313, there is no solder mask material nor metal layers inside the dimples 313. However, the shape of the opening of the dimples 313 is not limited. As shown in FIG. 5, the shape of the openings of the dimples 313 can be rectangular or polygonal.

As shown in FIG. 5, the chip 320 is disposed in the chip mounting region 314 on the top surface 311 of the substrate 310. In the present embodiment, as shown in FIG. 4, the chip 320 has a plurality of bumps 322 formed on the active surface 321 of the chip 320 where the chip 320 is flip-chip mounted to the substrate 310 aligned with the chip mounting region 314. The encapsulant 330 is formed on the top surface 311 of the substrate 310 to encapsulate the chip 320, but not encapsulate the bottom surface 312 nor the edges of the substrate 310. As shown in FIG. 4, in the present embodiment, the dimples 313 are mechanically bonded by the encapsulant 330 without any electrical transmission to increase the adhesive strength between the substrate 310 and the encapsulant 330 to avoid delamination and to enhance product reliability and quality. The semiconductor package 300 has the enhanced adhesion of the encapsulant 330 and the increased diffusion path of moisture to achieve functions of anti-humidity and anti-delamination.

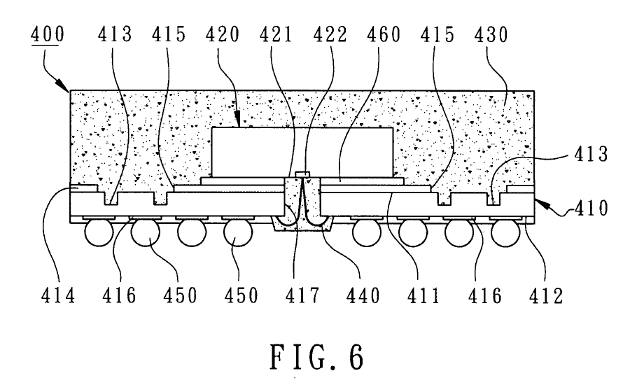

In the third embodiment, another semiconductor package 400 is revealed as shown in FIG. 6, primarily comprising a substrate 410, a chip 420, and an encapsulant 430. The substrate 410 has a top surface 411 and a plurality of dimples 413 formed on the top surface 411. The top surface 411 includes a chip mounting region corresponding to the footprint of the chip 420, not shown in the figure. The dimples 413 are located outside the chip mounting region without penetrating through the substrate 410 and without any electrical transmission. As shown in FIG. 6, the substrate 410 further has a solder mask 414 formed on the top surface 411 of the substrate 410. The solder mask 414 has at least a window 415 or slot to expose the dimples 413. In the present embodiment, the dimples 413 are formed in the core of the substrate 410 by punching.

The active surface 421 of the chip 420 is attached to the top surface 411 of the substrate 410 by a die-attaching layer 460 so that the chip 420 is disposed on the chip mounting region. In the present embodiment, the substrate 410 has a slot 417. The semiconductor package 400 further has a plurality of bonding wires 440 passing through the slot 417 to electrically connect a plurality of bonding pads 422 of the chip 420 to the substrate 410. The encapsulant 430 is formed on the top surface 411 of the substrate 410 and in the slot 417 to encapsulate the chip 420 and the bonding wires 440. Furthermore, the semiconductor package 400 further has a plurality of solder balls 450 disposed on a plurality of outer pads 416 formed on the bottom surface 412 of the substrate 410.

The above description of embodiments of this invention is intended to be illustrative and not limiting. Other embodiments of this invention will be obvious to those skilled in the art in view of the above disclosure.

What is claimed is:

1. A semiconductor package comprising:
a substrate having a top surface and a plurality of dimples formed in the top surface, wherein the top surface includes a chip mounting region, the dimples are located at a non-wiring region outside the chip mounting region but not penetrate through the substrate;
a chip disposed on the chip mounting region; and
an encapsulant formed on the top surface of the substrate to encapsulate the chip and the dimples.

2. The semiconductor package of claim 1, wherein the dimples are adjacent to the peripheries of the top surface of the substrate.

3. The semiconductor package of claim 1, wherein the dimples have a plurality of openings in the form selected from the group consisting of a circle, a rectangle, and a polygon.

4. The semiconductor package of claim 1, wherein the depth of the dimples ranges from one tenth to one half of the substrate thickness.

5. The semiconductor package of claim 1, wherein most of the dimples are located at the corners of the top surface of the substrate.

6. The semiconductor package of claim 1, wherein the dimples are blind vias formed by mechanical drilling.

7. The semiconductor package of claim 1, wherein the dimples are selected from the group consisting of laser-drilled holes and punched indentations.

8. The semiconductor package of claim 1, wherein the substrate further has a solder mask formed on the top surface of the substrate.

9. The semiconductor package of claim 8, wherein the solder mask is further formed in the dimples.

10. The semiconductor package of claim 8, wherein the solder mask has a plurality of openings as the same with those of the dimples in dimensions.

11. The semiconductor package of claim 8, wherein the solder mask has a window to expose the dimples.

12. The semiconductor package of claim 1, wherein the dimples are mechanically bonded by the encapsulant without any electrical transmission.

13. The semiconductor package of claim 1, wherein the chip includes a plurality of bumps for flip-chip mounting to the substrate.

14. The semiconductor package of claim 1, further comprising a plurality of bonding wires electrically connecting the chip to the substrate.

15. The semiconductor package of claim 1, wherein the substrate further has a plurality of outer pads formed on a bottom surface of the substrate.

16. The semiconductor package of claim 15, further comprising a plurality of solder balls disposed on the outer pads.
